(19) United States
(12) Patent Application Publication
(10) Pub. No.: US 2020/0381314 A1
(43) Pub. Date: Dec. 3, 2020

(54) Method for Providing Coated Leadframes or for Measuring an Adhesion Force of an Encapsulant on a Leadframe

(71) Applicant: Infineon Technologies AG, Neubiberg (DE)

(72) Inventors: Wu Hu Li, Singapore (SG); Stefan Schwab, Regensburg (DE); Verena Muhr, Regensburg (DE); Edmund Riedl, Wald (DE); Alexander Roth, Zeitlarn (DE); Harry Sax, Straubing (DE)

(21) Appl. No.: 16/884,756

(22) Filed: May 27, 2020

(30) Foreign Application Priority Data
May 28, 2019 (DE) 102019114242.3

(51) Int. Cl. H01L 21/66; H01L 21/48; B05D 1/02; C25D 3/22; C25D 5/18; C25D 7/12

(52) U.S. Cl. CPC H01L 22/20; H01L 21/4821; C25D 7/12; C25D 3/22; C25D 5/18; B05D 1/02

(57) ABSTRACT

A method for providing coated leadframes in a process line includes: feeding a plurality of leadframes successively into a process line; depositing a layer onto a main face of the leadframes; measuring physical properties of the layer by one of ellipsometry or reflectometry; assigning measured physical data to any one of a plurality of categories; and depending on a resulting category of the measured physical data, altering process parameters of the depositing, not altering the process parameters of the depositing, or shutting down the process line.

### TECHNICAL FIELD

The present disclosure is related to a method for providing coated leadframes in a process line and to an apparatus for providing coated leadframes in a process line. The present disclosure is also related to a method for measuring an adhesion force of an encapsulant on leadframes and to an apparatus for measuring an adhesion force of an encapsulant on leadframes.

### BACKGROUND

Semiconductor packages are often fabricated by employing a leadframe as a substrate for one or more semiconductor dies. Amongst other process steps of the fabrication, the leadframe and the semiconductor dies are encapsulated by any kind of plastic or resin material in a molding process. In this respect the degree of adhesion of the encapsulant to the leadframe is of very high significance. In order to increase the degree of adhesion, very often thin coatings, so-called adhesion promotors, are applied to the leadframe surface before the molding process. Also, other layers like anti-tarnish and/or anti-epoxy-bleed-out layers can be applied to the leadframe in order to further improve the properties of the semiconductor package to be fabricated. If any of such layers are employed, it may become important to gain knowledge about the quality of these layers. Besides that, it will be important to know more about the degree of adhesion between the encapsulant and the coated or uncoated leadframe.

### SUMMARY

A first aspect of the present disclosure is related to a method for providing coated leadframes in a process line, comprising providing a plurality of leadframes and feeding them successively into a process line, depositing a layer onto a main face of the leadframes, measuring physical properties of the layer by one of ellipsometry or reflectometry and assign measured physical properties or properties derived from measured physical properties to either one of a number of categories, and depending on a resulting category, either altering process parameters of the depositing process, or not altering the process parameters of the depositing process, or shutting down the process line.

A second aspect of the present disclosure is related to a method for measuring an adhesion force of an encapsulant on leadframes, the method comprising removing a test body from a leadframe and thereby measuring a force required to remove the test body.

A third aspect of the present disclosure is related to an apparatus for providing coated leadframes in a process line, the apparatus comprising a deposition apparatus configured to deposit a layer onto a main face of the leadframes, a measurement apparatus configured to measure physical properties of the layer by one of ellipsometry or reflectometry and to assign measured physical properties or properties derived from measured physical properties to either one of a number of categories, and a controller device configured to cause the deposition apparatus to either alter process parameters of the deposition process, or not to alter the process parameters of the deposition process, or to shut down the process line, depending on a resulting category.

A fourth aspect of the present disclosure is related to an apparatus for measuring an adhesion force of an encapsulant on leadframes, the apparatus comprising a shear tester, which is disposed so that it removes a test body from an incoming leadframe, and a force measuring device connected with the shear tester.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description.

The elements of the drawings are not necessarily to scale relative to each other. Like reference numerals designate corresponding similar parts.

FIG. 1 shows an exemplary flow diagram of a method according to the first aspect.

FIG. 2 shows an exemplary flow diagram of a method according to the first aspect, the method incorporating a feedback loop to adjust process parameters for the coating process.

FIG. 3 shows a schematic representation of the measurement principle of an ellipsometer.

FIGS. 4A and 4B show respective diagrams illustrating examples for the assigning of ellipsometrically measured physical data on A2 layers to either one of a number of categories wherein the categories are determined by ranges of the measured amplitude component Ψ and phase difference Δ (FIG. 4A) and determined thicknesses and standard deviation of thicknesses (FIG. 4B).

FIGS. 5A and 5B show respective diagrams illustrating examples for the dependency of the ellipsometry measured amplitude component Ψ and phase difference Δ on the wavelength of the incident light for a Cu substrate (FIG. 5A) and a NiP substrate (FIG. 5B), with and without an A2 layer, respectively.

FIGS. 6A and 6B show respective schematic representations of an exemplary apparatus according to the third aspect including A2 layer plating comprising inline/in-situ ellipsometry or reflectometry at a location behind the dryer (FIG. 6A) and at a location at the final rinsing (FIG. 6B).

FIGS. 7A and 7B show respective schematic representations of an exemplary apparatus according to the third aspect comprising inline/in-situ ellipsometry or reflectometry at silane sprayed layers (FIG. 7A) and anti-tarnish and/or anti EBO (epoxy-bleed-out) layers (FIG. 7B).

FIGS. 8A to 8F show respective schematic representations of different measurement configurations of the ellipsometry and reflectometry measurements concerning the spatial relative positions of the light source, the detector, and the moving sample.

FIG. 9 shows a schematic top view representation of an exemplary leadframe layout illustrating different possibilities for measuring all units or only a selected portion of the units.

FIG. 10 shows a top view onto a semiconductor die connected with a leadframe to illustrate the different possible measurements locations.

FIG. 11 shows an exemplary flow diagram of a method according to the second aspect.

FIG. 12 shows schematic side view representations of an apparatus for measuring an adhesion force of an encapsulant on leadframes according to the fourth aspect.

### DETAILED DESCRIPTION

In the following detailed description, reference is made to the accompanying drawings, which form a part hereof, and in which is shown by way of illustration specific embodiments in which the invention may be practiced. In this regard, directional terminology, such as “top”, “bottom”, “front”, “back”, “leading”, “trailing”, etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

As employed in this specification, the terms “bonded”, “attached”, “connected”, “coupled” and/or “electrically connected/electrically coupled” are not meant to mean that the elements or layers must directly be contacted together; intervening elements or layers may be provided between the “bonded”, “attached”, “connected”, “coupled” and/or “electrically connected/electrically coupled” elements, respectively. However, in accordance with the disclosure, the above-mentioned terms may, optionally, also have the specific meaning that the elements or layers are directly contacted together, i.e. that no intervening elements or layers are provided between the “bonded”, “attached”, “connected”, “coupled” and/or “electrically connected/electrically coupled” elements, respectively.

Further, the word “over” used with regard to a part, element or material layer formed or located “over” a surface may be used herein to mean that the part, element or material layer be located (e.g. placed, formed, deposited, etc.) “indirectly on” the implied surface with one or more additional parts, elements or layers being arranged between the implied surface and the part, element or material layer. However, the word “over” used with regard to a part, element or material layer formed or located “over” a surface may, optionally, also have the specific meaning that the part, element or material layer be located (e.g. placed, formed, deposited, etc.) “directly on”, e.g. in direct contact with, the implied surface.

FIG. 1 shows a flow diagram for illustrating an example of the method of the first aspect. The method 10 for providing coated leadframes in a process line according to FIG. 1 comprises providing a plurality of leadframes and feeding them successively into a process line (11), depositing a layer onto a main face of the leadframes (12), measuring physical properties of the layer by one of ellipsometry or reflectometry and assign measured physical properties or properties derived from measured physical properties to either one of a number of categories (13), and depending on a resulting category, either altering process parameters of the depositing process, or not altering the process parameters of the depositing process, or shutting down the process line (14).

According to an example of the method of FIG. 1, the layer can be either one of a Zn alloy based adhesion promotor layer (in the following “A2 layer”), a silane layer, an anti-tarnish and/or anti-epoxy-bleed-out layer.

The method 10 of FIG. 1 thus includes an in-situ monitoring of the layer quality and a feedback loop to the deposition device for altering process parameters in case that the measured or derived physical properties are interpreted such that the quality of the layer cannot be judged satisfactory.

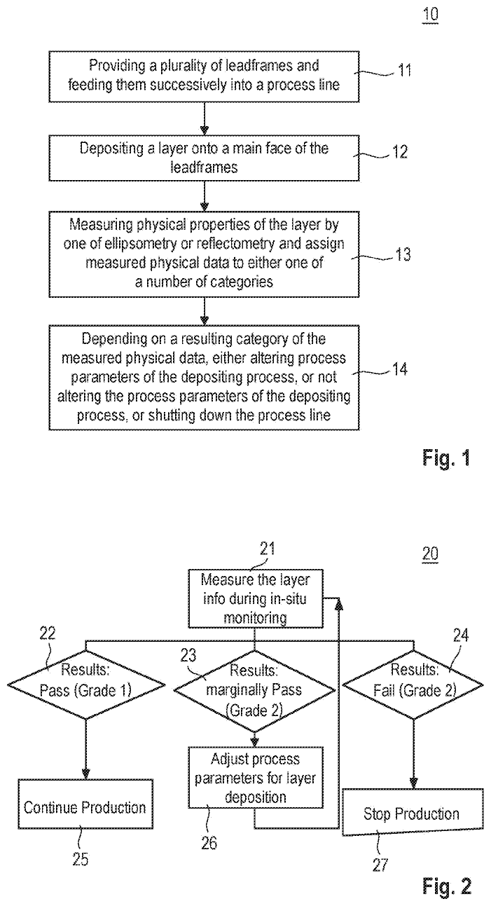

FIG. 2 is another flow diagram which illustrates an example of the feedback loop implemented in the method of FIG. 1. The method 20 of FIG. 2 comprises an in-situ monitoring by measuring physical data of the layer (21) wherein “layer info” may refer to measured physical properties and/or properties derived from measured physical properties. The obtained results can then be categorized into three different grades, namely grade 1 (22), grade 2 (23), and grade 3 (24). Grade 1 means that the measured data were interpreted satisfactory so that the production can be continued (25). Grade 2 means that the results were interpreted not satisfactory, but still so that the quality defects can be judged as marginal which results in an adjustment process of the parameters of the layer deposition (26). The production and the in-situ monitoring will then be continued (see arrow from 26 to 21). Grade 3 means that the results were interpreted not satisfactory to a degree that the quality defects can no further be judged as marginal which results in a stopping of the production process (27).

According to an example of the method of FIG. 1 or 2, the method further comprises measuring physical properties by ellipsometry.

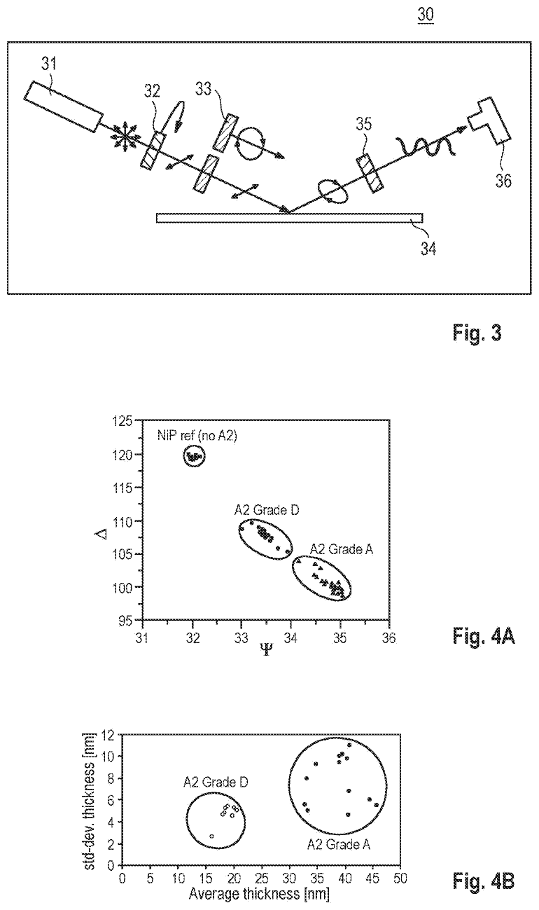

FIG. 3 shows the measurement principle of an ellipsometer.

Ellipsometry is an optical measurement technique to analyze the change of polarization of a light beam that is reflected from a sample surface. Single-wavelength ellipsometry employs a monochromatic light source (usually a laser) as incident light whereas spectroscopic ellipsometry (SE) employs broad band light sources, which cover a certain spectral range in the infrared, visible or ultraviolet spectral region. Such broad band light sources can be, for example, Xenon lamps or white light LEDs. The advantage of laser ellipsometry is that laser beams can be focused on a small spot size. Lasers also can have a higher power and intensity than broad band light sources. With both single-wavelength and spectroscopic ellipsometry one can differentiate the various samples by measuring two parameters, namely the amplitude component Ψ and the phase difference Δ. From these parameters, other properties of the layer like, for example, a thickness, a thickness variation, the complex refractive index, or the dielectric function tensor can be derived.

According to FIG. 3 an ellipsometer 30 comprises a light source 31, and then in the beam path of the emitted light beam one after the other, a rotating polarizer 32, a quarter wave plate 33, and after reflection from the surface of a sample 34, an analyzer 35, and a detector 36.

FIGS. 4A and 4B show respective diagrams illustrating examples for the assigning of ellipsometrically measured physical data on A2 layers to either one of a number of categories.

According to FIG. 4A, there is shown an example of a single wavelength (632.8 nm) ellipsometry measurement on an A2 coating on NiP surfaces. The categories “Grade A” and “Grade D” are determined by ranges of the measured parameters Ψ and Δ. As a reference there are shown measured data for a pure NiP surface without an A2 layer which data show a good separation from the data of the A2 coated samples. When comparing FIG. 4A with the flow diagram of FIG. 2, samples categorized in Grade A would for example correspond to Grade 1 which would mean a continued production, whereas samples categorized in Grade D would for example correspond to Grade 2 which would mean the instigation of an adjustment of the deposition parameters or even Grade 3 which would mean a stop of the production.

According to FIG. 4B, there is shown an example of a spectroscopic ellipsometry measurement on a A2 layer wherein the physical data derived from the measurements are the thicknesses and the standard deviation of the thicknesses of the respective A2 layers. Accordingly the categories “Grade A” and “Grade D” are determined by ranges of the determined thicknesses and standard deviation of thicknesses. Again there can be seen a good separation between “Grade A” and “Grade D” samples. When comparing FIG. 4B with the flow diagram of FIG. 2, samples categorized in Grade A would for example correspond to Grade 1 which would mean a continued production, whereas samples categorized in Grade D would for example correspond to Grade 2 which would mean the instigation of an adjustment of the deposition parameters or even Grade 3 which would mean a stop of the production. With respect to FIGS. 4A and 4B, beside Grade A and Grade D, there can also be Grade B and Grade C, wherein Grade A and B can be Grade 1 (pass), C can be Grade 2 (marginally pass), and Grade D can be Grad 3 (fail).

Various wavelengths from ultraviolet (UV) to near infrared (NIR) range could be chosen for both laser ellipsometry and spectroscopic ellipsometry. The choice of wavelength depends very much on the system, in particular the coating and the surfaces, to be detected.

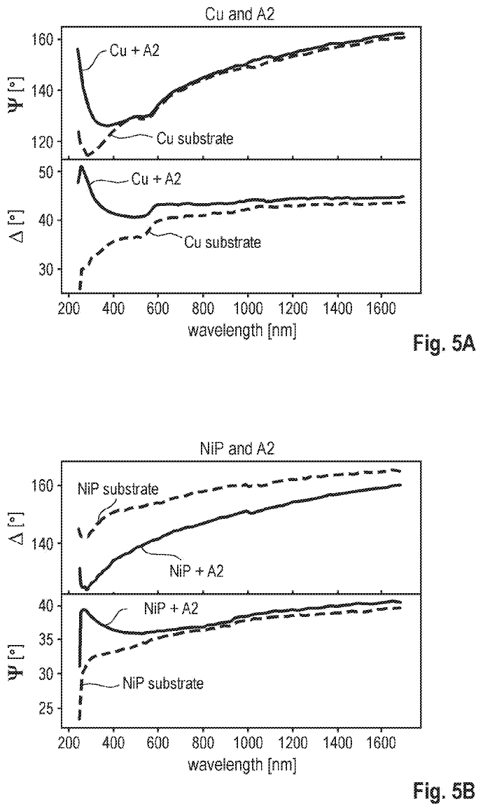

FIGS. 5A and 5B show respective diagrams illustrating examples for measured physical data and their dependency on the wavelength of the incident light.

FIG. 5A shows the dependency of the ellipsometrically measured amplitude component Ψ and the phase difference Δ on the wavelength of the incident light for a Cu substrate with and without an A2 layer. The data show that, for example, at an incident wavelength of 628.8 nm there is a difference of the Ψ values between the curves whereas their Δ difference is very small. Furthermore the difference of both Ψ and Δ values becomes much bigger in the UV range.

FIG. 5B shows the dependency of the ellipsometrically measured amplitude component Ψ and the phase difference Δ on the wavelength of the incident light for a NiP substrate, with and without an A2 layer. The data show that, for example, at an incident wavelength of 628.8 nm the difference of Ψ values between the curves is small while the difference of their Δ values is very significant. Furthermore, the difference of both Ψ and Δ values becomes much bigger in the UV range. Although optical and geometrical challenges are identical for both 450 nm and 632.8 nm, a reduction of the wavelength, for example from 632.8 nm to 450 nm, increases the difference of the Ψ and Δ values (with A2 vs. without A2 coating) significantly.

According to an example of the method of FIG. 1, measuring physical properties of the layer by ellipsometry comprises measuring the physical properties by imaging ellipsometry.

As already mentioned above, the method of FIG. 1 may comprise measuring physical properties of the layer by reflectometry. In reflectometry a light beam is impinging on the substrate surface and the intensity of a reflected light beam can be measured by a sensor. In particular, the measurements can be performed in the form of reflectance spectroscopy which is essentially the investigation of the spectral composition of surface-reflected radiation with respect to its angularly dependent intensity and the composition of the incident primary radiation.

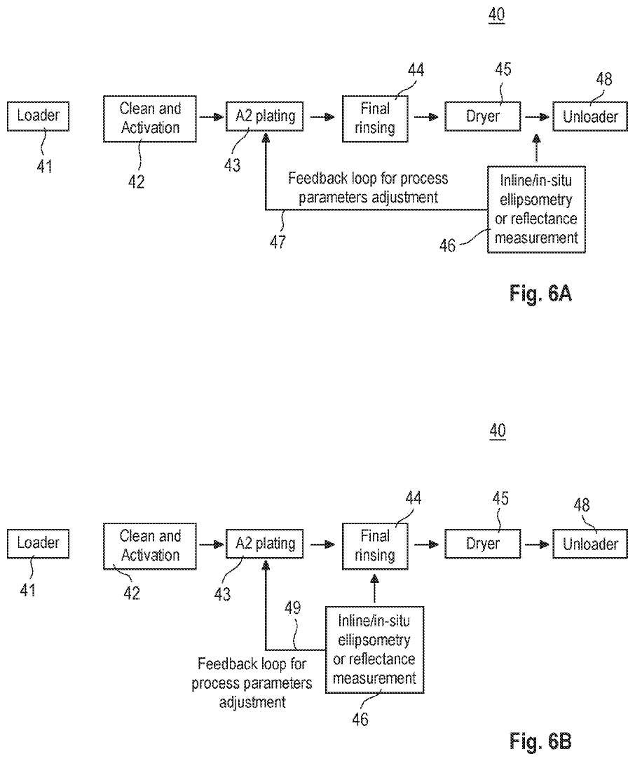

FIGS. 6A and 6B show respective schematic representations of exemplary apparatuses according to the third aspect.

According to FIG. 6A there is shown a process line 40 which includes A2 layer plating comprising inline/in-situ ellipsometry or reflectance measurement at a location behind a dryer. In particular, the process line 40 comprises a loader 41 which loads leadframes into the process line 40. In particular, the loader 41 conveys the leadframes to a clean and activation device 42. From there the leadframes are delivered to an A2 plating device 43 wherein the mode of operation of the A2 plating device 43 will be explained later. After the A2 plating device 43 the leadframes are conveyed to a rinsing device 44 which is followed by a dryer 45. Behind the dryer 45 there is a measurement device 46 configured to perform the inline/in-situ ellipsometry or reflectance measurement. The measurement device 46 is coupled by a feedback line 47 to the A2 plating device 43 to change the process parameters of the A2 plating device if necessary. At the end of the process line 40 there is provided an unloader 48 for unloading the leadframes out of the process line 40.

According to FIG. 6B there is shown a process line 40 which includes A2 layer plating comprising inline/in-situ ellipsometry or reflectance measurement at the final rinsing device 44. All other components are identical to the process line 40 of FIG. 6A. The measurement device 46 is disposed at a location parallel to the final rinsing device 44. As well in this case, the measurement device 46 is coupled by a feedback line 49 to the A2 plating device 43 to change the process parameters of the A2 plating device if necessary.

The deposition process of the A2 layer comprises an electrolytic deposition wherein a pulsed electric current is applied to the leadframe and the electrolyte, wherein the process parameters are given by the pulse amplitude, i.e. the peak current of the pulses, the current direction, i.e. reversing the current direction or applying pulses with alternating current direction, the pulse duration, and the flow rate of the electrolyte. It should be mentioned that these parameters can be adjusted temporarily to safe yield in case of any offset of the quality of the A2 layer.

When it will be determined in the control loop that the process parameters have to be changed, it can be done in the following way. It may be found that the quality of the A2 layer is not satisfying, in particular if the A2 layer comprises some degree of porosity. In a first step, one of the process parameters will be changed, in particular the pulse amplitude will be increased. This will lead to a higher overvoltage at the surface that will overcome any inhibition of the surface. Thereafter, if the quality of the A2 layer is still determined to be not satisfying, in a further step another one of the process parameters will be changed, in particular the current direction will be changed or pulses with alternating current direction will be applied. This will lead to an even stronger activation of the surface due to reverse current that dissolves specific passivation layers. Thereafter, if the quality of the A2 layer is still determined to be not satisfying, in a further step another one of the process parameters will be changed, in particular the flow rate of the electrolyte will be increased. Thereafter, if the quality of the A2 layer is still determined to be not satisfying, the belt has to be run empty. This means, stop loading of further leadframes and clearing the process line regarding the leadframes already loaded to the belt. After this, the machine goes to stop after which the operator's assistance is required.

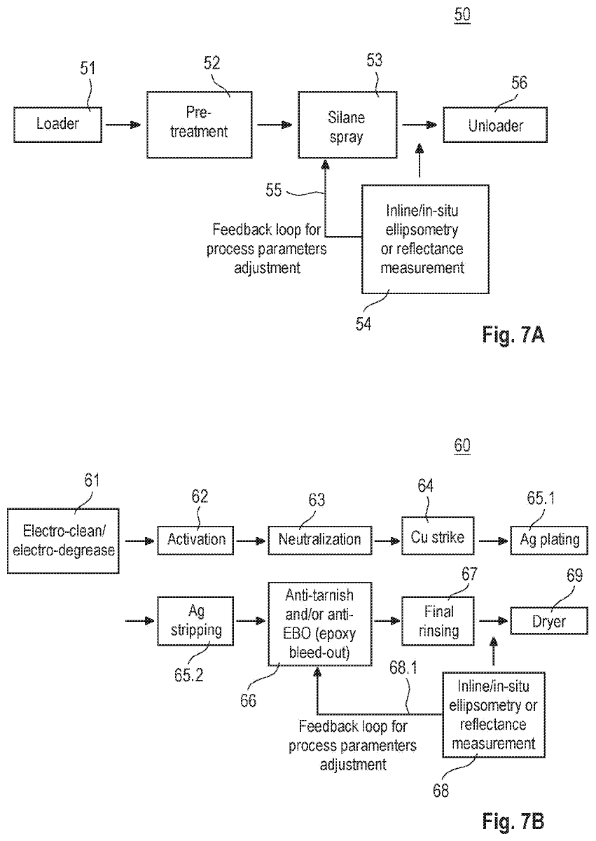

FIGS. 7A and 7B show respective schematic representations of exemplary apparatuses according to the third aspect.

According to FIG. 7A there is shown a process line 50 which includes silane layer coating comprising inline/in-situ ellipsometry or reflectance measurement at a location behind a silane spray apparatus. In particular, the process line 50 comprises a loader 51 which loads leadframes into the process line 50. In particular, the loader 51 conveys the leadframes to a pre-treatment device 52. From there the leadframes are delivered to a silane spray apparatus 53 wherein the mode of operation of the silane spray apparatus 53 will be explained later. Behind the silane spray apparatus 53 there is a measurement device 54 configured to perform the inline/in-situ ellipsometry or reflectance measurement. The measurement device 54 is coupled by a feedback line 55 to the silane spray apparatus 53 to change the process parameters of the silane spray apparatus 53 if necessary. At the end of the process line 50 there is provided an unloader 56 for unloading the leadframes out of the process line 50.

The deposition process of the silane layer comprises a spray deposition, wherein the process parameters are given by a spray volume, in particular via a conveyor speed or a carrier gas pressure, and the spray time, in particular via a transfer speed of the leadframe. It should be mentioned that these parameters can be adjusted temporarily to safe yield in case of any offset of the quality of the silane layer.

When it will be determined in the control loop that the process parameters have to be changed, it can be done in the following way. It may be found that the quality of the silane layer is not satisfying, in particular the thickness is too low. In a first step, one of the process parameters will be changed, in particular the spray volume will be increased. Thereafter, if the quality of the silane layer is still determined to be not satisfying, in a further step another one of the process parameters will be changed, in particular the substrate speed underneath the spray nozzles will be reduced. Thereafter if the quality of the silane layer is still determined to be not satisfying, in a further step another one of the process parameters will be changed, in particular a second spray sequence will be run on the respective leadframe. Thereafter, if the quality of the silane layer is still determined to be not satisfying, the belt has to be run empty. This means, stop loading of further leadframes and clearing the process line regarding the leadframes already loaded to the belt. After this, the machine goes to stop after which the operator's assistance is required.

According to FIG. 7B there is shown a process line 60 which includes the coating of an anti-tarnish and/or anti-EBO (epoxy-bleed-out) layer comprising inline/in-situ ellipsometry or reflectance measurement at a location behind a final rinsing device. In particular, the process line 60 comprises a device 61 for electro-clean/electro-degrease of leadframes. Thereafter the leadframes are conveyed to an activation device 62 and from there to a neutralization device 63. From there the leadframes are conveyed to a Cu strike device 64 for plating a very thin Cu layer. Thereafter a structured Ag layer is formed by an Ag plating device 65.1 and an Ag stripping device 65.2. From there the leadframes are delivered to a deposition apparatus 66 for depositing an anti-tarnish and/or anti-EBO (epoxy-bleed-out) layer wherein the mode of operation of the deposition apparatus 66 will be explained later. Thereafter the leadframes are conveyed to a final rinsing device 67. Behind the final rinsing device 67 there is a measurement device 68 configured to perform the inline/in-situ ellipsometry or reflectance measurement. The measurement device 68 is coupled by a feedback line 68.1 to the deposition apparatus 66 to change the process parameters of the deposition apparatus 66 if necessary. At the end of the process line 60 there is provided a dryer 69 for drying the leadframes.

The deposition process of the anti-tarnish and/or anti-EBO (epoxy-bleed-out) layer comprises dipping the leadframe into a liquid bath of a solution of an anti-tarnish and/or anti-EBO (epoxy-bleed-out) material, wherein the process parameters are given by one or more of a concentration of the anti-tarnish material, a temperature of the bath, and a dipping time of the leadframe into the bath. It should be mentioned that these parameters can be adjusted temporarily to safe yield in case of any offset of the quality of the anti-tarnish and/or anti-EBO (epoxy-bleed-out) layer.

When it will be determined in the control loop that the process parameters have to be changed, it can be done in the following way. In a first step, one of the process parameters will be changed, in particular the concentration of the anti-tarnish and/or anti-EBO material will be increased. Thereafter, if the quality of the anti-tarnish and/or anti-EBO (epoxy-bleed-out) layer is still determined to be not satisfying, in a further step another one of the process parameters will be changed, in particular the temperature of the bath will be increased. Thereafter if the quality of the anti-tarnish and/or anti-EBO (epoxy-bleed-out) layer is still determined to be not satisfying, in a further step another one of the process parameters will be changed, in particular the dipping time of the leadframe into the bath will be increased. Thereafter, if the quality of the anti-tarnish and/or anti-EBO (epoxy-bleed-out) layer is still determined to be not satisfying, the belt has to be run empty. This means, stop loading of further leadframes and clearing the process line regarding the leadframes already loaded to the belt. After this, the machine goes to stop after which the operator's assistance is required.

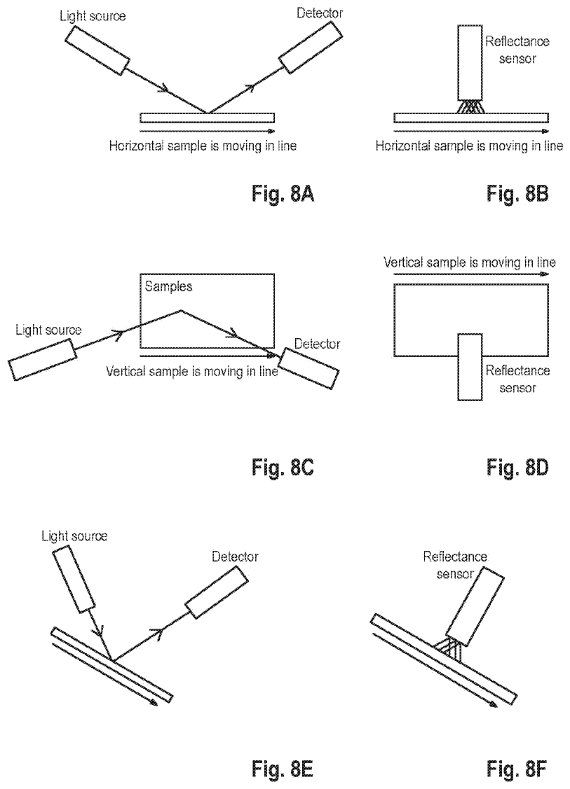

FIGS. 8A to 8F illustrate different measurement configurations of the ellipsometry and reflectometry measurements concerning the spatial relative positions of the light source, the detector, and the moving sample. In each one of the Figures for the sake of clarity only the essential elements of the measurement setup are shown.

FIGS. 8A and 8B show configurations with a horizontally oriented sample moving to the right as indicated by the arrow. The ellipsometry measurement can be done as shown in FIG. 8A with light source and detector at different positions and the light beam reflected under an angle <90° at the sample surface. The reflectance measurement can be done in the same way or as shown in FIG. 8B with light source and detector at essentially the same positions and the light beam reflected at the sample surface under an angle of essentially 0°, namely perpendicular to the measurement surface.

FIGS. 8C and 8D show configurations with a sample in a vertical upright position moving to the right as indicated by the arrow. The ellipsometry measurement can be done as shown in FIG. 8C with light source and detector at different positions before one of the side faces of the sample and the light beam reflected under an angle <90° at the sample surface. The reflectance measurement can be done in the same way or as shown in FIG. 8D with light source and detector at essentially the same positions before one of the side faces of the sample and the light beam reflected at the sample surface under an angle of essentially 0°, namely perpendicular to the measurement surface.

FIGS. 8E and 8F show configurations with a horizontally tilted sample moving in a tilted direction to the right down with the supporting of rollers as indicated by the arrow. The ellipsometry measurement can be done as shown in FIG. 8E with light source and detector at different positions and the light beam reflected under an angle <90° at the sample surface. The reflectance measurement can be done in the same way or as shown in FIG. 8F with light source and detector at essentially the same positions and the light beam reflected at the sample surface under an angle of essentially 0°, namely perpendicular to the measurement surface.

It should be mentioned that the measurements can be done while the sample is moving so that measured data are taken from different locations on the sample and the measured data are integrated by a circuitry in an evaluating circuit after the detector. On the other hand, the measurements can also be done with a stationary sample so that measured data are taken only from one location of the sample.

It should further be mentioned that the integration of the ellipsometer (or the reflectance sensor) could be done not only in air, but also in the process tank with solution, such as inside DI (de-ionized water), or any other solution with or without chemicals. Of course, there are more things to be considered when integrating it into a solution tank. Such a setup could be realized as follows.

In a configuration as shown in FIGS. 8C and 8D,

i) the ellipsometer could be placed outside of the tank, the incident beam will travel through a window (e.g. made from glass) of the tank to the sample and then the reflected beam travels through the window and back into the detector.
ii) the ellipsometer could also be sealed and placed directly inside of the tank.

In a configuration as shown in FIGS. 8A and 8B or in FIGS. 8E and 8F,

i) if there is no cover on the top of the tank, the ellipsometer could be placed from top side (similar to the measurement in air).
ii) if there is a cover on top of tank,
a) the ellipsometer could be placed from top of tank, the incident beam will travel through a window (e.g. made from glass) of the tank to the sample and then the reflected beam travels through the window and back into the detector.
b) the ellipsometer could also be sealed and placed directly inside of the tank.

In order to in-situ measure the layer, the ellipsometer and the reflectometer may have a fast measurement speed, namely short measurement time (e.g. 0.0001 to 10 second/data) to meet the line speed of plating or spray line (for example, from 0.01 to 10 meter/minute). The measurement time/speed depends on a few factors, such as

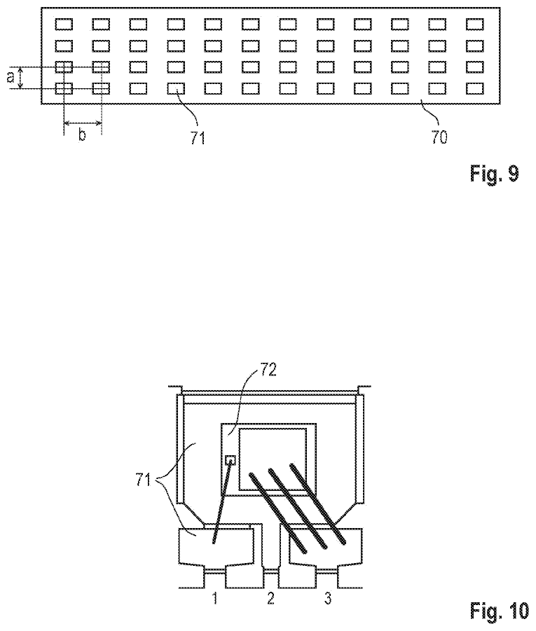

a. the line speed of plating or spray machine (for example, from 0.01 to 10 meter/minute).
b. the sampling size. For example in FIG. 9, there is a 12 columns×4 rows matrix in a leadframe layout or frame 70. The pitches for the rows and columns is a and b, respectively. We can select from measuring all these units 71 in the frame 70, all units 71 in only one or some of rows or columns, some of the units 71 in only one or some of rows or columns. For example, when the frame 70 is moving horizontally, we could measure all or some of the units 71 in one particular row.

FIG. 10 shows a top view onto a semiconductor die connected with a leadframe to illustrate the different possible measurements locations. The measurement location on a sample like the one shown in FIG. 10 could be:

a. Leadframe 71 and/or chip surfaces 72 (in package assembly process): to measure the coating (e.g. A2 or silane coating) on the chip (e.g. bond pad, polyimide etc.) or leadframe surface (die paddle, lead area etc.).
b. Leadframe surface (in leadframe manufacturing or assembly process): to measure the final coating, such as anti-tarnish and/or anti-epoxy-bleed-out (EBO) chemicals, on Ag, Ni, NiP, NiNiP, NiPdAu, NiPdAuAg etc. plated metal surfaces (e.g. Cu, alloy42, steel, aluminum, brass etc.).

The following solutions can be considered for challenges to measure on moving products in terms of focus of beam line:

During product (sample) movement, product is running out of focus continuously due to swinging and angle variations of product to the beam. This problem can be solved or minimized by following methods:
a. Measure many values with fast speed, based on the intensities of signal (set up threshold) to pick up the valid values and omit the data out of focus.
b. Fast measurements and only take these measurements that can be fitted into the model and then be considered the valid data. The measurements which don't fit into the model are deleted.
c. Keep the distance between the sample and the detector as short as possible to minimize the impact of reflected beam on tilted surface (moving object).
d. Make the moving sample as stable as possible, such as providing track to guide the sample top and bottom.
e. Rotation of ellipsometer to compensate offset error of moving object.
f. Increase size of detector to cater for swing of moving object.

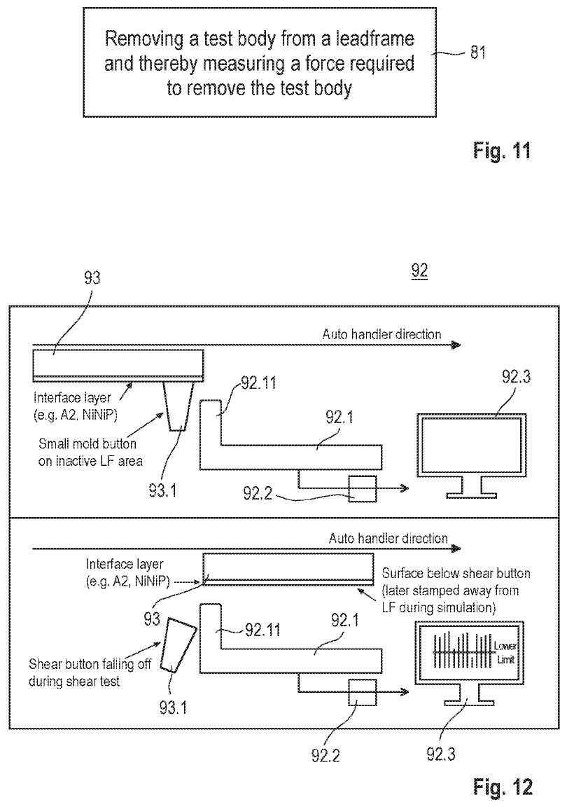

FIG. 11 shows a flow diagram for illustrating an example of the method of the second aspect. The method 80 for measuring an adhesion force of an encapsulant on leadframes comprises removing a test body from a leadframe and thereby measuring the force required to remove the test body (81).

According to an example of the method of FIG. 11 the test body is disposed in a downward configuration on the leadframe wherein removing the test body comprises collecting the falling test body in a bucket.

According to an example of the method of FIG. 11, the test body comprises the form of a cube or a cone.

According to an example of the method of FIG. 11, the method further comprises removing the test body by a shear tester, in particular by a stationary shearing chisel, wherein the leadframe is transported in such a way that the test body hits against the shearing chisel.

An encapsulant can be applied to a leadframe, the encapsulant including a test body, wherein the apparatus can, for example, be a conventional molding apparatus like, e.g. a transfer molding apparatus, or a compression molding apparatus. According to an example the apparatus is configured to apply the test body in a downward configuration so that it can fall down into a bucket after having been removed from the leadframe. The leadframe may comprise a layer or coating between its main face and the encapsulant. The layer can be an adhesion promotor layer or any one of the layers which were described above in connection with the other aspects of this disclosure.

FIG. 12 shows schematic side view representations of an apparatus 92 according to the fourth aspect. The apparatus 92 of FIG. 12 comprises a shear tester 92.1, which is disposed so that it removes a test body 93.1 from an incoming leadframe 93, and a force measuring device 92.2 connected with the shear tester 92.1. The shear tester 92.1 may comprise a stationary shearing chisel 92.11, which is disposed in such a way that the leadframe 93 hits with the test body 93.1 against the shearing chisel 92.11. Each time when the leadframe 93 hits against the shearing chisel 92.11, the force which is required to remove the test body 93.1 is measured by the force measuring device 92.2. The force measuring device 92.2 can be connected to a monitor 92.3 on which the shearing force values can be displayed. Also displayed on the monitor 92.3 can be a lower limit of the shearing force. When a measured value of the shearing force falls under this lower limit, it is an indication that the adhesion force was too low. In this case it is, for example, possible to discard the respective leadframe or group of leadframes.

The test body 93.1 can be applied onto a non-used portion of the leadframe 93 as, for example, an edge portion, a portion between the wires, etc. Also more than one test body can be applied onto the leadframe, in particular onto process critical portions of the leadframes.

According to an example of the apparatus 92 of FIG. 12, the apparatus 92 can be part of or integrated in one of further production tools that can be used in the production processes after molding. In particular, the apparatus 92 could be integrated in a stamping tool or a deflash tool.

The removal of the test body could be carried out in a consecutive way by an automated handler system. This system could be for instance integrated in one of the following process equipment, such as:
the stamping tool, where all the devices attached to one leadframe are singulated/stamped.
the plating tool which is used to plate the pins of the devices after molding.
the deflashing equipment which is used to remove mold flash from the backside of the leadframe.

Furthermore Data Matrix Code (DMC) can be employed for electronically collecting and associating the measured data of the shearing force. These data collections can also be used as a quality feature and communicated as such to the customers together with the delivered products.

### EXAMPLES

Example 1 is a method for providing coated leadframes in a process line, comprising providing a plurality of leadframes and feeding them successively into a process line, depositing a layer onto a main face of the leadframes, measuring physical properties of the layer by one of ellipsometry or reflectometry and assign measured physical properties or properties derived from measured physical properties to either one of a number of categories, and depending on a resulting category, either altering process parameters of the depositing process, or not altering the process parameters of the depositing process, or shutting down the process line.

Example 2 is a method according to Example 1, further comprising measuring physical properties by single wavelength laser ellipsometry, wherein the measured physical properties comprise the amplitude component Ψ and the phase difference Δ, and the categories are determined by ranges of Ψ and Δ.

Example 3 is a method according to Example 1, further comprising measuring physical properties by spectroscopic ellipsometry, wherein a broad band light source is employed emitting light in a particular spectral region.

Example 4 is a method according to any one of the Examples 1 to 3, wherein the properties derived from the measured physical properties comprise one or more of a thickness, a thickness variation, the complex refractive index, or the dielectric function tensor at the single wavelength or in the particular spectral region.

Example 5 is a method according to any one of the preceding Examples wherein the layer is a Zn alloy based adhesion promotor layer, and the depositing process comprises an electrolytic deposition wherein a pulsed electric current is applied to the leadframe and the electrolyte, wherein the process parameters are given by the pulse amplitude, the current direction, the pulse duration, and the flow rate of the electrolyte.

Example 6 is a method according to any one of Examples 1 to 4, wherein the layer is a silane layer, and the depositing process comprises a spray deposition, wherein the process parameters are given by a spray volume, in particular via a conveyor speed or a carrier gas pressure, and the spray time, in particular via a transfer speed of the leadframe.

Example 7 is a method according to any one of Examples 1 to 4, wherein the layer is an anti-tarnish layer, and the depositing process comprises dipping the leadframe into a liquid bath of a solution of an anti-tarnish material, wherein the process parameters are given by one or more of a concentration of the anti-tarnish material, a temperature of the bath, and a dipping time.

Example 8 is a method according to any one of Examples 1 to 4, wherein the layer is an anti-epoxy-bleed layer, and the depositing process comprises dipping the leadframe into a liquid bath of a solution of an anti-epoxy-material, wherein the process parameters are given by one or more of a concentration of the anti-tarnish material, a temperature of the bath, and a dipping time.

Example 9 is a method for measuring an adhesion force of an encapsulant on leadframes, the method comprising removing a test body from a leadframe and thereby measuring a force required to remove the test body.

Example 10 is a method according to Example 9, further comprising prior to the removing step, forming the test body on the leadframe.

Example 11 is a method according to Example 10, wherein the test body is formed on the leadframe by applying an encapsulant to the leadframe, wherein the step of forming the test body is performed at the same time of encapsulating a semiconductor device.

Example 12 is a method according to any one of Examples 9 to 11, wherein during the removing step the test body is positioned downwardly so that it can fall down after having been removed from the leadframe.

Example 13 is a method according to Example 9, wherein the test body is disposed in a downward configuration on the leadframe wherein removing the test body comprises collecting the falling test body in a bucket.

Example 14 is a method according to Example 9 or 10, wherein the test body comprises the form of a cube or a cone.

Example 15 is a method according to any one of Examples 9 to 11, further comprising removing the test body by a stationary shearing chisel, wherein the leadframe is transported in such a way that the test body hits against the shearing chisel.

Example 16 is an apparatus for providing coated leadframes in a process line, the apparatus comprising a deposition apparatus configured to deposit a layer onto a main face of the leadframes, a measurement apparatus configured to measure physical properties of the layer by one of ellipsometry or reflectometry and to assign measured physical data to either one of a number of pre-determined categories, and a controller device configured to cause the deposition apparatus to either alter process parameters of the deposition process, or not to alter the process parameters of the deposition process, or to shut down the process line, depending on a resulting category of the measured physical data.

Example 17 is an apparatus according to Example 16, wherein the process line comprises a rinsing device and thereafter a drying device, wherein the measurement apparatus is inserted after the drying device, in particular when the layer is a Zn based adhesion promotion layer.

Example 18 is an apparatus according to Example 16, wherein the measurement apparatus is inserted after the deposition apparatus, in particular when the layer is a silane layer and the deposition apparatus is a spraying apparatus.

Example 19 is an apparatus according to Example 16, wherein the layer is an anti-tarnish layer and the depositing apparatus comprises a liquid bath of a solution of an anti-tarnish material for dipping the leadframe into the liquid bath.

Example 20 is an apparatus according to Example 16, wherein the layer is an anti-epoxy-bleed layer and the depositing apparatus comprises a liquid bath of a solution of an anti-epoxy-bleed material for dipping the leadframe into the liquid bath.

Example 21 is an apparatus for measuring an adhesion force of an encapsulant on leadframes according to a fourth aspect, comprising a shear tester, which is disposed so that it removes a test body from an incoming leadframe, and a force measuring device connected with the shear tester.

Example 22 is an apparatus according to Example 21, wherein the shear tester comprises a stationary shearing chisel.

Example 23 is an apparatus according to Example 21 or 22, further comprising a monitor, the force measuring device being connected to the monitor wherein the monitor is configure to display measured shearing force values and a lower limit of the shearing force.

In addition, while a particular feature or aspect of an embodiment of the invention may have been disclosed with respect to only one of several implementations, such feature or aspect may be combined with one or more other features or aspects of the other implementations as may be desired and advantageous for any given or particular application. Furthermore, to the extent that the terms “include”, “have”, “with”, or other variants thereof are used in either the detailed description or the claims, such terms are intended to be inclusive in a manner similar to the term “comprise”. Furthermore, it should be understood that embodiments of the invention may be implemented in discrete circuits, partially integrated circuits or fully integrated circuits or programming means. Also, the term “exemplary” is merely meant as an example, rather than the best or optimal. It is also to be appreciated that features and/or elements depicted herein are illustrated with particular dimensions relative to one another for purposes of simplicity and ease of understanding, and that actual dimensions may differ substantially from that illustrated herein.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method for providing coated leadframes in a process line, the method comprising:
feeding a plurality of leadframes successively into a process line;
depositing a layer onto a main face of the leadframes;
measuring physical properties of the layer by one of ellipsometry or reflectometry;
assigning measured physical properties or properties derived from the measured physical properties to any one of a plurality of categories; and
depending on a resulting category, altering process parameters of the depositing, not altering the process parameters of the depositing, or shutting down the process line.

2. The method of claim 1, wherein the physical properties are measured by single wavelength laser ellipsometry, wherein the measured physical properties comprise an amplitude component Ψ and a phase difference Δ, and wherein the categories are determined by ranges of Ψ and λ.

3. The method of claim 1, wherein the physical properties are measured by spectroscopic ellipsometry, and wherein a broad band light source is employed emitting light in a particular spectral region.

4. The method of claim 1, wherein the properties derived from the measured physical properties comprise one or more of a thickness, a thickness variation, a complex refractive index, or a dielectric function tensor at a single wavelength or in a particular spectral region.

5. The method of claim 1, wherein the layer is a Zn alloy based adhesion promotor layer, wherein the depositing comprises an electrolytic deposition during which a pulsed electric current is applied to the leadframes and an electrolyte, and wherein the process parameters are given by a pulse amplitude, a current direction, a pulse duration, and a flow rate of the electrolyte.

6. The method of claim 1, wherein the layer is a silane layer, wherein the depositing comprises a spray deposition, and wherein the process parameters are given by a spray volume and a spray time.

7. The method of claim 6, wherein the spray volume is given by a conveyor speed or a carrier gas pressure, and wherein the spray time is given by a transfer speed of the leadframes.

8. The method of claim 1, wherein the layer is an anti-tarnish layer, wherein the depositing comprises dipping the leadframes into a liquid bath of a solution of an anti-tarnish material, and wherein the process parameters are given by one or more of a concentration of the anti-tarnish material, a temperature of the bath, and a dipping time.

9. The method of claim 1, wherein the layer is an anti-epoxy-bleed layer, wherein the depositing comprises dipping the leadframes into a liquid bath of a solution of an anti-epoxy-material, and wherein the process parameters are given by one or more of a concentration of the anti-tarnish material, a temperature of the bath, and a dipping time.

10. An apparatus for providing coated leadframes in a process line, the apparatus comprising:
a deposition apparatus configured to implement a deposition process that includes depositing a layer onto a main face of the leadframes;
a measurement apparatus configured to measure physical properties of the layer by one of ellipsometry or reflectometry, and to assign measured physical data to any one of a plurality of pre-determined categories; and
a controller device configured to cause the deposition apparatus to either alter process parameters of the deposition process, or not to alter the process parameters of the deposition process, or to shut down the process line, depending on a resulting category of the measured physical data.

11. The apparatus of claim 10, wherein the process line comprises a rinsing device and thereafter a drying device, and wherein the measurement apparatus is inserted after the drying device.

12. The apparatus of claim 11, wherein the layer is a Zn based adhesion promotion layer.

13. The apparatus of claim 10, wherein the measurement apparatus is inserted after the deposition apparatus.

14. The apparatus of claim 13, wherein the layer is a silane layer and the deposition apparatus is a spraying apparatus.

15. The apparatus of claim 10, wherein the layer is an anti-tarnish layer, and wherein the depositing apparatus comprises a liquid bath of a solution of an anti-tarnish material for dipping the leadframes into the liquid bath.

16. The apparatus of claim 10, wherein the layer is an anti-epoxy-bleed layer, and wherein the depositing apparatus comprises a liquid bath of a solution of an anti-epoxy-bleed material for dipping the leadframes into the liquid bath.
